(19) United States
(12) Patent Application Publication
(10) Pub. No.: US 2024/0427969 A1
(43) Pub. Date: Dec. 26, 2024

(54) Recommendation Approach for Modeling of Processes

(71) Applicant: SAP SE, Walldorf (DE)

(72) Inventors: Diana Sola, Heidelberg (DE); Andreas Gerber, Koenigsbach-Stein (DE)

(21) Appl. No.: 18/341,289

(22) Filed: Jun. 26, 2023

(51) Int. Cl. G06F 30/27; G06F 40/40; G06Q 10/067

(52) U.S. Cl. CPC G06F 30/27; G06F 40/40; G06Q 10/067

(57) ABSTRACT

Embodiments afford recommendations in the accurate modeling of complex process flows. A repository is provided of known models (in graph form) of complex processes. Semantics of the repository models, are constrained within an existing vocabulary (e.g., one that does not include a particular term). During an initial training phase, a fine-tuned sequence-to-sequence language model is generated from a pre-trained language model (e.g., T5) and semantics of the known repository process models, using transfer-learning techniques (e.g., from Natural Language Processing—NLP). During runtime, an incomplete process model (also in graph form) is received having an unlabeled node. Embodiments provide a node label recommendation based upon the fine-tuned sequence-to-sequence language model. The node label that is recommended, is in a vocabulary which extends beyond the repository vocabulary (e.g., includes the particular term). In this manner, accuracy and/or flexibility of modeling of complex processes (e.g., node label recommendation) can be enhanced.

### BACKGROUND

Unless otherwise indicated herein, the approaches described in this section are not prior art to the claims in this application and are not admitted to be prior art by inclusion in this section.

Process flows are widely encountered in many fields of knowledge. For example, organizations may perform processes in order to deliver services or products to customers.

It may be desirable to create a model of such process flows, for example in the context of computer processing. However, establishing such process models can be time-consuming and error-prone. This can be attributable to reliance upon knowledge of details of a specific process by domain experts, who themselves may not be familiar with model creation.

### SUMMARY

Embodiments afford recommendations in the accurate modeling of complex process flows. A repository is provided of known models (in graph form) of complex processes. Semantics expressed by the repository models, are constrained within an existing vocabulary (e.g., one that does not include a particular term). During an initial training phase, a fine-tuned sequence-to-sequence language model is generated from a pre-trained language model (e.g., T5) and semantics of the known repository process models, using transfer-learning techniques (e.g., from Natural Language Processing—NLP). During runtime, an incomplete process model (also in graph form) is received having an unlabeled node. Embodiments afford a recommendation of a label for that node, based upon the fine-tuned sequence-to-sequence language model. The resulting recommended node label, is expressed in a vocabulary that extends beyond the limited vocabulary of the repository (e.g., includes the particular term). In this manner, accuracy and/or flexibility of modeling a complex process flow (e.g., affording a node label recommendation), can be enhanced.

The following detailed description and accompanying drawings provide a better understanding of the nature and advantages of various embodiments.

### BRIEF DESCRIPTION OF THE DRAWINGS

FIG. 1 shows a simplified diagram of a system according to an embodiment.

FIG. 2 shows a simplified flow diagram of a method according to an embodiment.

FIG. 3 shows one example of a process flow.

FIG. 4 shows another example of a process flow.

FIG. 5A shows a first list of output sequences according to an example.

FIG. 5B shows a second list of output sequences according to the example.

FIG. 5C lists final label recommendations according to the example.

FIG. 6 illustrates hardware of a special purpose computing machine configured to implement process modeling according to an embodiment.

FIG. 7 illustrates an example computer system.

### DETAILED DESCRIPTION

Described herein are methods and apparatuses that implement process modeling. In the following description, for purposes of explanation, numerous examples and specific details are set forth in order to provide a thorough understanding of embodiments according to the present invention. It will be evident, however, to one skilled in the art that embodiments as defined by the claims may include some or all of the features in these examples alone or in combination with other features described below, and may further include modifications and equivalents of the features and concepts described herein.

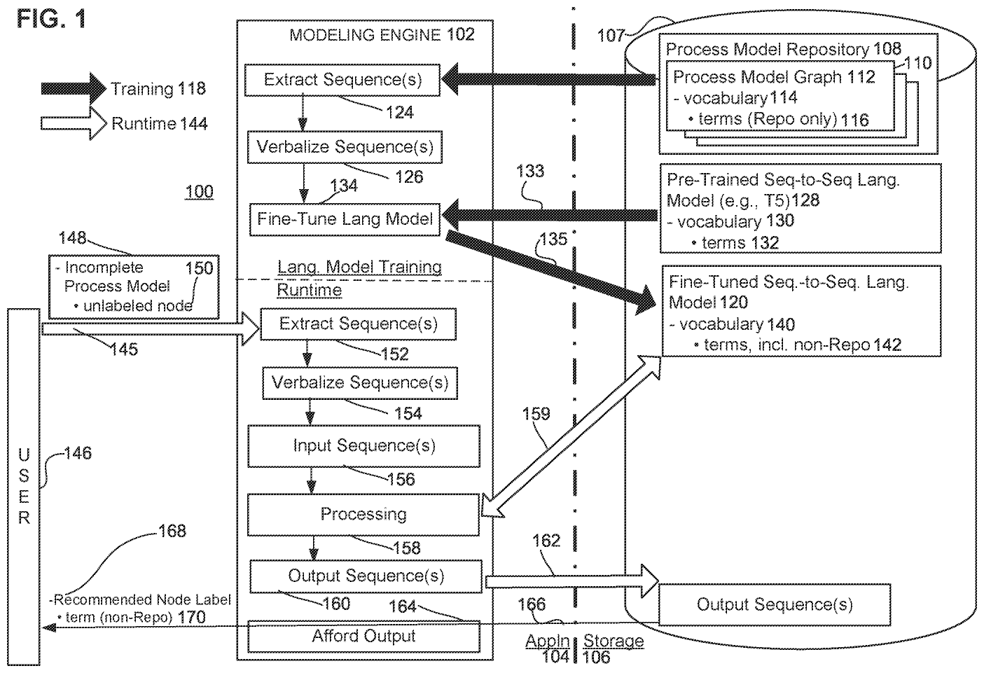

FIG. 1 shows a simplified view of an example system that is configured to implement process modeling according to an embodiment. Specifically, system 100 comprises a modeling engine 102 that is present in an application layer 104 overlying a storage layer 106 including a database 107.

The storage layer includes a process model repository 108. This repository comprises a number of different known process models 110 in the form of graphs 112 (e.g., including nodes and edges). One specific example of a graph is a directed attribute graph.

Each of the known process models further includes a respective vocabulary 114 comprising terms 116. Examples of such terms can be labels for specific nodes of the existing process model.

During a training phase 118, the modeling engine seeks to create an enriched, fine-tuned language model 120, relying on transfer learning techniques. That fine-tuned model includes a vocabulary 140 of a scope extending beyond the existing vocabulary of the models in the repository.

Accordingly, the modeling engine creates the fine-tuned language model by extracting 124 sequences from models of the repository. Next, the modeling engine verbalizes 126 the extracted sequences.

The storage layer also includes a pre-trained sequence-to-sequence language model 128 (one possible example of which is T5). The pre-trained language model includes a vocabulary 130 comprising term(s) 132 not present in any of the models of the repository.

Accordingly, the modeling engine references 133 the pre-trained language model and the verbalized extracted sequences to generate 134 the fine-tuned language model 120. That fine-tuned model is stored 135 in the storage layer. The fine-tuned model language model comprises a vocabulary 140 that includes terms 142 outside of the model repository.

Next, during a runtime 144 the modeling engine receives 145 from a user 146, an incomplete process model 148. That incomplete process model is also in graph form, comprising nodes and edges.

However, the incoming process model received from the user is incomplete. That is, the incomplete process model features at least one node 150 that is not labeled.

In order to recommend a label for the node(s), the modeling engine extracts 152 sequences from the incomplete model. Then, the modeling engine verbalizes 154 those extracted sequences to create input sequences 156.

Then, the input sequences are processed 158 according to the fine-tuned language model. This may comprise activity recommendation processing 159. The resulting output sequences 160 are ranked and stored 162 in the database.

Next, in order to afford 164 an output to the user, the output sequences are retrieved 166. These output sequences include at least one recommended node label 168 that includes a term 170 that is not present in existing vocabularies of the known repository models.

Process modeling performed according to embodiments, may offer one or more benefits. One possible benefit is increased accuracy.

In particular, process model recommendation relying upon a repository, may find limited applicability in situations where a process model under development includes activities not present in the models of the repository. That is, embodiments relying upon the model repository can only recommend activity labels (or, at best, combinations of label parts) which already exist in the repository. This can limit the scope of recommended labels, and reduce a usefulness of recommendation for modeling of new processes.

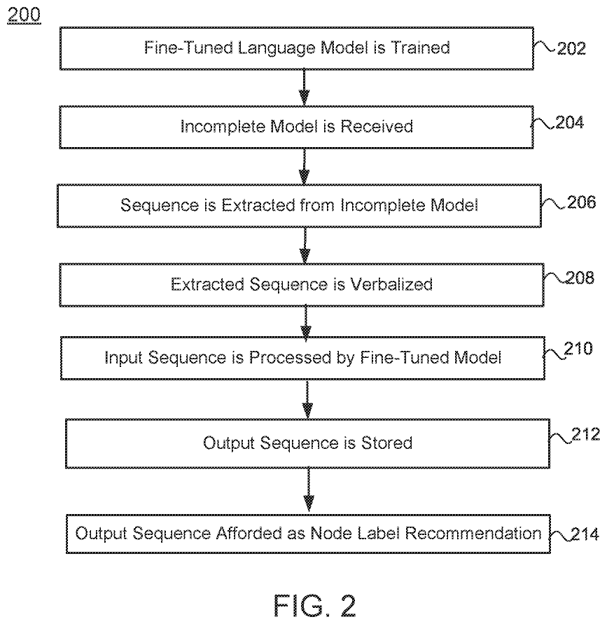

FIG. 2 is a flow diagram of a method 200 according to an embodiment. At 202, a fine-tuned language model is trained from a pre-trained language model and a process model repository.

At 204, an incomplete process model is received. At 206, a sequence is extracted from the incomplete process model.

At 208, the sequence is verbalized to create an input sequence. At 210, the input sequence is processed by the fine-tuned language model to generate an output sequence.

At 212, the output sequence is stored. At 214, the output sequence is afforded as a label recommendation for an unlabeled node of the incomplete process model.

Further details regarding process modeling according to various embodiments, are now provided in connection with the following example. In this particular example, process modeling is implemented based upon Business Process Model and Notation (BPMN).

### Example

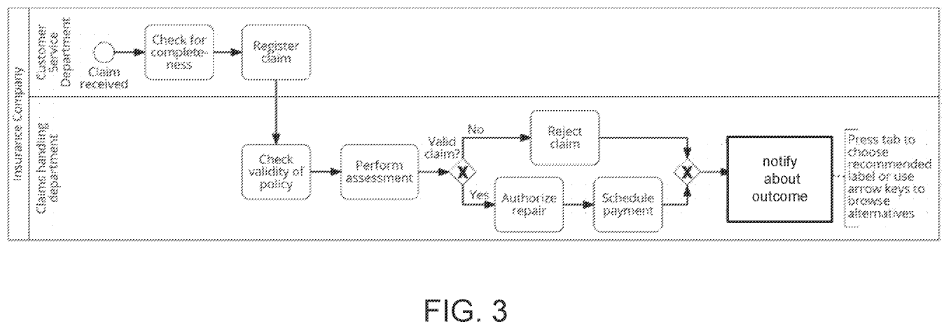

FIG. 3 shows a simplified view of an example incomplete process model for which a node recommendation is to be provided. The process flow modeled here, is for handling of a customer's claim against an insurance company. That insurance company has at least two distinct departments:
the customer service department (upper), and
the claims handling department (lower).

The BPMN model in FIG. 3 depicts a process flow that starts when an insurance claim is received from a claimant, after which various activities are performed to handle that claim. This process flow involves a decision point (indicated by an XOR-split gateway —diamond shape with an X), where a claim is either rejected, or payment is authorized and then scheduled.

Following this decision point, the model synchronizes the two branches using an XOR-join gateway. After this gateway, a new activity has been inserted.

The activity-recommendation task is to suggest one or more suitable labels for that new activity. As shown in FIG. 3, a recommended label is: “notify about outcome”.

This recommended label is appropriate here, because the preceding nodes indicate that the outcome of handling of the claim has now been determined. Following this outcome, it is natural and appropriate to seek to inform the insurance claimant.

Modeling of this insurance claim process, may be complicated by one or more factors. For example, in cross-departmental settings (such as is shown in FIG. 3), ensuring clarity and consistency in established process models is difficult, but appropriate in order to avoid process execution/analysis based on incorrect, incomplete, or inconsistent models.

Another factor complicating accurate formation of a process model, is that an individual possessing specialized knowledge of the process domain (e.g., insurance claim handling), may likely be unfamiliar with even the general outline of how to create a model of such a process.

Accordingly, this example offers an approach for activity recommendation which uses a transformer-based, sequence-to-sequence language model (e.g., T5). This transformer-based, sequence-to-sequence language model extends recommendation capabilities to models and activities above and beyond those specifically available in training data (e.g., an existing repository of known process models).

Sequence-to-sequence models may call for ordered, textual sequences as input, whereas process model nodes can be only partially ordered. Thus, a first phase may be to lift activity recommendation to the format of sequence-to-sequence tasks.

Sequence-to-sequence tasks are concerned with finding a model that maps a sequence of inputs (x₁, . . . , x_{T}) to a sequence of outputs (y₁, . . . , y_{T}′). The output length T′ is unknown a priori, and may differ from the input length T.

One example of a sequence-to-sequence problem in NLP, is machine translation. There, the input sequence is given by text in a source language. The output sequence is the translated text in a target language.

In the context of activity recommendation, the output sequence corresponds to the activity label λ(\hat{n}) to be recommended for node \hat{n}. This may comprise one or more words, e.g., “notify about outcome” as shown in FIG. 3.

Defining the input sequence can be more complex. This is because the input to an activity-recommendation task comprises an incomplete process model M₁, whose nodes may be partially ordered rather than forming a single sequence.

Thus, embodiments convert a single activity-recommendation task, into one or more sequence-to-sequence tasks. To accomplish this, embodiments first extract multiple node sequences from M₁ that each end in \hat{n}.

Formally, we write that S_{l\hat{n}}=(n₁, . . . , nₗ) is a node sequence of length l, ending in node \hat{n} (nₗ=\hat{n}), for which it must hold that nᵢ is a predecessor of nᵢ₊₁ for all i=1, . . . , l−1.

Then, since an input sequence should comprise text (rather than model nodes), embodiments apply verbalization to the node sequence. This verbalization strings together the types and (cleaned) labels of the nodes in S_{l\hat{n}}, i.e., τ(nₗ)λ(n₁) . . . τ(nₗ₋₁)λ(nₗ₋₁)τ(\hat{n}).

For example, using sequences of length four (4), we obtain the following two (2) verbalized input sequences for the recommendation problem in FIG. 3:

| # | Textualized Input Sequence |
|---|---|
| 1 | task authorize repair task schedule payment xor task |
| 2 | xor valid claim task reject claim xor task |

This sequence extraction and verbalization, is used to fine-tune a transformer-based sequence—to sequence model (e.g., T5) for activity recommendation. Specifically, having lifted activity recommendation to the format of sequence-to-sequence tasks, embodiments may then fine-tune a transformer-based sequence-to-sequence model for activity recommendation based on process knowledge encoded in a process model repository.

In one example, we fine-tune a transformer-based sequence-to-sequence model (such as T5) for activity recommendation. This is done by extracting a large number of sequence-to-sequence tasks from the models in an available process model repository [symbol] . Specifically, for each model M∈ [symbol] , we extract possible sequences of a certain length l that end in an activity node, i.e., (n₁, . . . , nₗ).

Afterwards, we apply verbalization on this node sequence to get the textual input sequence, as described above. Whereas, the output sequence corresponds to the label of nₗ.

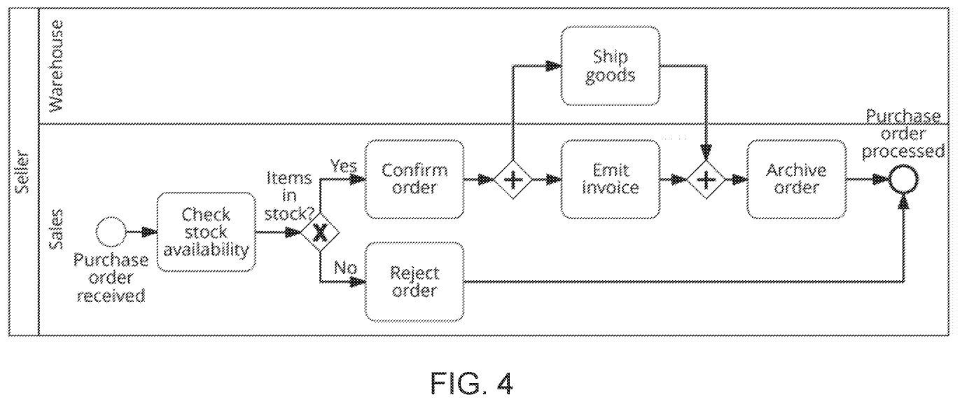

As one possible example, consider the exemplary training process model (stored within a repository) that is depicted in FIG. 4. This training process model is an order-to-cash process flow for a seller receiving a purchase order.

Setting l=4, the training process model comprises nine (9) sequences of length four (4), that end in an activity node. Following verbalization, these nine sequences result in the following textual (input,output) sequences:

| | | Textual Output |
|---|---|---|
| # | Textual Input Sequence | Sequence |
| 1 | start purchase order received task | confirm order |
| | check stock availability xor items | |
| | in stock task | |
| 2 | start purchase order received task | reject order |
| | check stock availability xor items | |
| | in stock task | |
| 3 | task check stock availability xor | purchase order |
| | items in stock task reject order end | processed |
| 4 | xor items in stock task confirm order | ship goods |
| | and task | |
| 5 | xor items in stock task confirm order | emit invoice |
| | and task | |
| 6 | and task ship goods and task | archive order |
| 7 | and task emit invoice and task | archive order |
| 8 | task ship goods and task archive order | purchase order |
| | end | processed |
| 9 | task emit invoice and task archive order | purchase order |
| | end | processed |

These can be used to fine-tune a transformer-based sequence-to-sequence language model (e.g., T5) for use in activity recommendation.

Once fine-tuned, the language model may be used to solve instances of the activity-recommendation problem. We first solve multiple sequence-to-sequence tasks, whose results are then aggregated in order to return one or more label recommendations.

Label recommendations may be generated as follows. Given an incomplete process model M₁ with an unlabeled activity node \hat{n}, for which we want to provide label recommendations, we first extract all sequences of length l that end in \hat{n}.

We then verbalize these sequences and feed the resulting input sequences as sequence-to-sequence tasks into the fine-tuned sequence-to-sequence model.

Looking again to the insurance claim process example of FIG. 3, this results in the two (2) input sequences described earlier when using l=4, which are:
I₁: task authorize repair task schedule payment xor task
I₂: xor valid claim task reject claim xor task

We solve the individual sequence-to-sequence tasks, by feeding each input sequence into the fine-tuned sequence-to-sequence model. This generates ten (10) alternative output sequences (i.e., 10 possible labels) per input.

To do this, we use beam search as a decoding method, with beam width w=10. The beam search procedure uses conditional probabilities to track the w most likely output sequences at each generation step.

The beam search procedure can lead to output sequences that repeat words or even short sequences, i.e., n-grams. Accordingly, following activity labeling convention, we favor the suggestion of short labels that do not contain any recurring terms. For example, rather than suggesting labels such as:
“check passport and check visa”,
   embodiments would suggest the non-repetitive alternative:
“check passport and visa”.

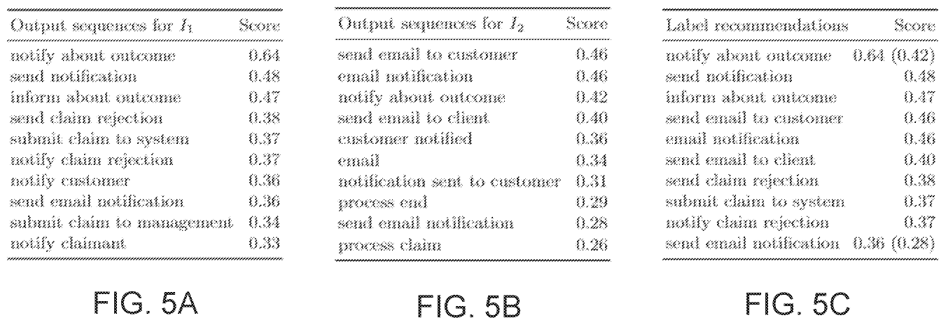

In order to achieve this, we apply n-gram penalties during beam search. Specifically, we penalize the repetition of n-grams of any size (including single words) by setting the probability of next words that are already included in the output sequence to zero. The tables shown in FIGS. 5A and 5B show the alternative output sequences (and probabilities) that the fine-tuned language model generates for input sequences I1 and I2, respectively.

Finally, we aggregate the different lists of output sequences obtained by using beam search to solve individual sequence-to-sequence tasks. We end up with a single list of ranked recommended activity labels.

The contents of the lists may be aggregated using a maximum strategy. This maximum strategy may be employed by rule-based methods to rank proposed entities according to the different confidence values of the rules that suggested them.

To apply the maximum strategy, we establish an aggregated recommendation list, sorted according to the maximal probability score that a recommended label received. For example the “notify about outcome” label receives a score of 0.64 from the output sequences generated for I1, even though that label also appears in I2's list (with a score of 0.42).

If two recommendations have the same maximum probability, we may sort them based on their second-highest probability, if available. Analogously, if two recommendations share maximum and second-highest probability, we continue until we find a probability that makes a difference.

In the end, this example embodiment thus provides a list of ten (10) ranked label recommendations for the unlabeled node \hat{n}, that are the most probable candidates. These recommendations are arrived at according to:
the sequences contained in the model under development,
the fine-tuned transformer-based sequence-to-sequence model, and
the maximum aggregation strategy.

The final list obtained for the running example, is shown in the table of FIG. 5C. Notably, the top five recommendations represent alternative manners to inform an insurance claimant (e.g., “notify about outcome”, “send notification”, or “send email to customer”). This indeed appears to be the appropriate process step given the current state of the sample process model under development.

It is noted that the instant example relates to processes models that are in the Business Process Model and Notation (BPMN) format. However, process modeling is not limited to this or any other specific process model notation format.

For example, embodiments could be applied to a process model in the Petri Nets graph notation, or in Unified Modeling Language (UML). Or, embodiments could be applied to any repository storing process models in abstracted form as directed attributed graphs.

And while the instant example describes beam search, this is not required. Other forms of decoding methods for language generation with transformer-based models, including random search involving sampling, could be employed.

Moreover, while the instant example describes aggregation using a maximum strategy, this is also not required. Other embodiments could employ other aggregation strategies, including a noisy OR approach.

Returning now to FIG. 1, there the particular embodiment is depicted with the modeling engine as being located outside of the database. However, this is not required.

Rather, alternative embodiments could leverage the processing power of an in-memory database engine (e.g., the in-memory database engine of the HANA in-memory database available from SAP SE), in order to perform one or more various functions as described above.

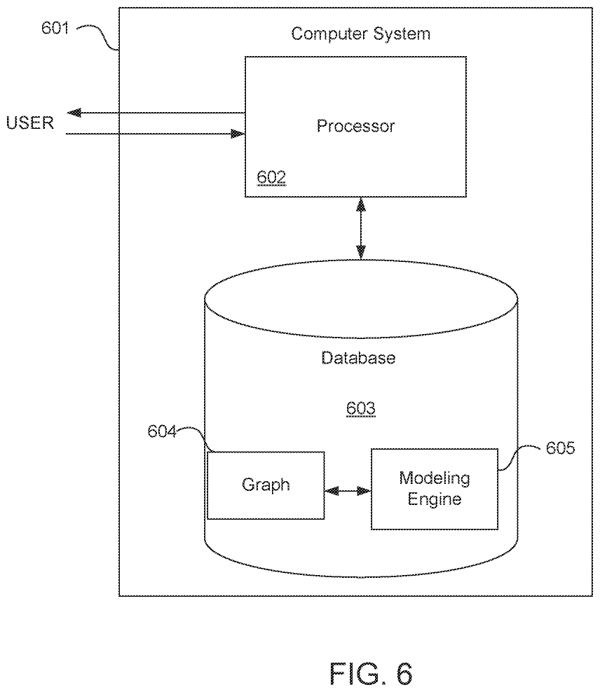

Thus FIG. 6 illustrates hardware of a special purpose computing machine configured to perform process modeling according to an embodiment. In particular, computer system 601 comprises a processor 602 that is in electronic communication with a non-transitory computer-readable storage medium comprising a database 603. This computer-readable storage medium has stored thereon code 605 corresponding to a modeling engine. Code 604 corresponds to a graph. Code may be configured to reference data stored in a database of a non-transitory computer-readable storage medium, for example as may be present locally or in a remote database server. Software servers together may form a cluster or logical network of computer systems programmed with software programs that communicate with each other and work together in order to process requests.

In view of the above-described implementations of subject matter this application discloses the following list of examples, wherein one feature of an example in isolation or more than one feature of said example taken in combination and, optionally, in combination with one or more features of one or more further examples are further examples also falling within the disclosure of this application:

Example 1. Computer implemented systems and methods comprising:
receiving an incomplete process model comprising a first graph having an unlabeled node;
extracting a sequence from the incomplete process model;
verbalizing the sequence to create an input sequence;
processing the input sequence as an activity-recommendation to a fine-tuned language model, the fine-tuned language model trained from a process model repository having a first vocabulary;
receiving from the processing, an output sequence including a term outside of the first vocabulary;
storing the output sequence in a non-transitory computer readable storage medium; and providing the output sequence as a label recommendation for the unlabeled node.

Example 2. The computer implemented systems or method of Example 1 further comprising:
prior to receiving the incomplete process model, training the fine-tuned language model by: extracting a training sequence from a process model comprising a second graph in the process model repository,
verbalizing the training sequence, and
providing the verbalized training sequence to a pre-trained language model.

Example 3. The computer implemented systems or methods of Examples 1 or 2 wherein the first graph comprises a directed attributed graph.

Example 4. The computer implemented systems or methods of Examples 1, 2, or 3 wherein the first graph is in the Business Process Modeling Notation (BPMN) format.

Example 5. The computer implemented systems or methods of Examples 1, 2, 3, or 4 further comprising:
also receiving from the processing, another output sequence;
ranking the output sequence and the another output sequence; and
providing the another output sequence as another label recommendation.

Example 6. The computer implemented systems or methods of Example 5 wherein the ranking comprises aggregating.

Example 7. The computer implemented systems or methods of Examples 5 or 6 wherein the ranking comprises a maximum strategy.

Example 8. The computer implemented systems or methods of Examples 1, 2, 3, 4, 5, 6, or 7 wherein the processing further comprises beam search.

Example 9. The computer implemented systems or methods of Example 8 wherein the processing further comprises calculating an n gram penalty.

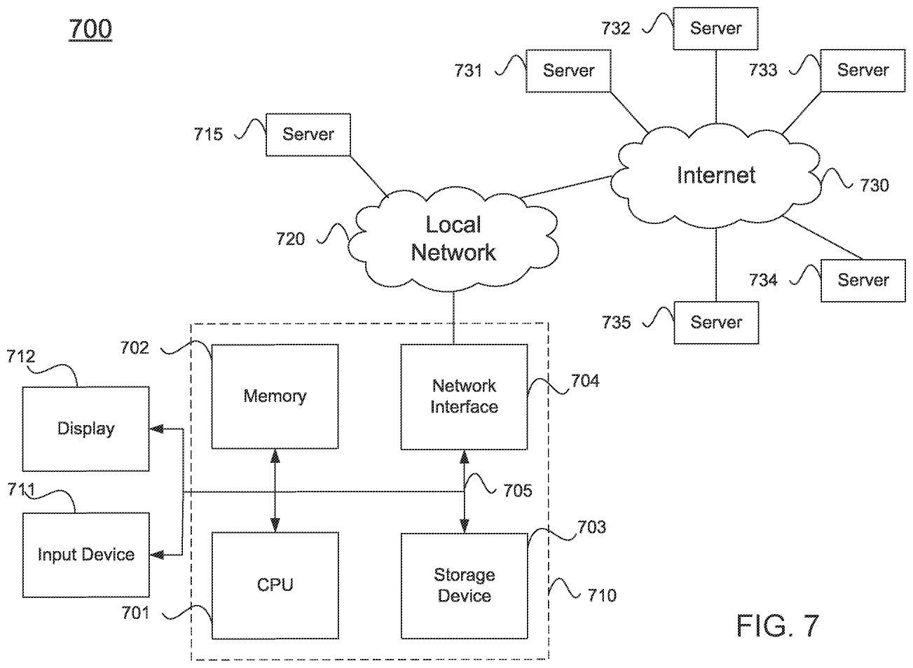

An example computer system 700 is illustrated in FIG. 7. Computer system 710 includes a bus 705 or other communication mechanism for communicating information, and a processor 701 coupled with bus 705 for processing information. Computer system 710 also includes a memory 702 coupled to bus 705 for storing information and instructions to be executed by processor 701, including information and instructions for performing the techniques described above, for example. This memory may also be used for storing variables or other intermediate information during execution of instructions to be executed by processor 701. Possible implementations of this memory may be, but are not limited to, random access memory (RAM), read only memory (ROM), or both. A storage device 703 is also provided for storing information and instructions. Common forms of storage devices include, for example, a hard drive, a magnetic disk, an optical disk, a CD-ROM, a DVD, a flash memory, a USB memory card, or any other medium from which a computer can read. Storage device 703 may include source code, binary code, or software files for performing the techniques above, for example. Storage device and memory are both examples of computer readable mediums.

Computer system 710 may be coupled via bus 705 to a display 712, such as a Light Emitting Diode (LED) or liquid crystal display (LCD), for displaying information to a computer user. An input device 711 such as a keyboard and/or mouse is coupled to bus 705 for communicating information and command selections from the user to processor 701. The combination of these components allows the user to communicate with the system. In some systems, bus 705 may be divided into multiple specialized buses.

Computer system 710 also includes a network interface 704 coupled with bus 705. Network interface 704 may provide two-way data communication between computer system 710 and the local network 720. The network interface 704 may be a digital subscriber line (DSL) or a modem to provide data communication connection over a telephone line, for example. Another example of the network interface is a local area network (LAN) card to provide a data communication connection to a compatible LAN. Wireless links are another example. In any such implementation, network interface 704 sends and receives electrical, electromagnetic, or optical signals that carry digital data streams representing various types of information.

Computer system 710 can send and receive information, including messages or other interface actions, through the network interface 704 across a local network z20, an Intranet, or the Internet 730. For a local network, computer system 710 may communicate with a plurality of other computer machines, such as server 715. Accordingly, computer system 710 and server computer systems represented by server 715 may form a cloud computing network, which may be programmed with processes described herein. In the Internet example, software components or services may reside on multiple different computer systems 710 or servers 731-735 across the network. The processes described above may be implemented on one or more servers, for example. A server 731 may transmit actions or messages from one component, through Internet 730, local network 720, and network interface 704 to a component on computer system 710. The software components and processes described above may be implemented on any computer system and send and/or receive information across a network, for example.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. Based on the above disclosure and the following claims, other arrangements, embodiments, implementations and equivalents will be evident to those skilled in the art and may be employed without departing from the spirit and scope of the invention as defined by the claims.

What is claimed is:

1. A method comprising:
receiving an incomplete process model comprising a first graph having an unlabeled node;
extracting a sequence from the incomplete process model;
verbalizing the sequence to create an input sequence;
processing the input sequence as an activity-recommendation to a fine-tuned language model, the fine-tuned language model trained from a process model repository having a first vocabulary;
receiving from the processing, an output sequence including a term outside of the first vocabulary;
storing the output sequence in a non-transitory computer readable storage medium; and
providing the output sequence as a label recommendation for the unlabeled node.

2. A method as in claim 1 further comprising:
prior to receiving the incomplete process model, training the fine-tuned language model by:
extracting a training sequence from a process model comprising a second graph in the process model repository,
verbalizing the training sequence, and
providing the verbalized training sequence to a pre-trained language model.

3. A method as in claim 1 wherein the first graph comprises a directed attributed graph.

4. A method as in claim 1 wherein the first graph is in the Business Process Modeling Notation (BPMN) format.

5. A method as in claim 1 further comprising:
also receiving from the processing, another output sequence;
ranking the output sequence and the another output sequence; and
providing the another output sequence as another label recommendation.

6. A method as in claim 5 wherein the ranking comprises aggregating.

7. A method as in claim 5 wherein the ranking comprises a maximum strategy.

8. A method as in claim 1 wherein the processing further comprises beam search.

9. A method as in claim 7 wherein the processing further comprises calculating an n gram penalty.

10. A non-transitory computer readable storage medium embodying a computer program for performing a method, said method comprising:
training a fine-tuned language model by,
extracting a training sequence from a process model comprising a graph in a process model repository, the process model repository having a first vocabulary,
verbalizing the training sequence, and
providing the verbalized training sequence to a pre-trained language model;
receiving an incomplete process model comprising another graph having an unlabeled node;
extracting a sequence from the incomplete process model;
verbalizing the sequence to create an input sequence;
processing the input sequence as an activity-recommendation to the fine-tuned language model;
receiving from the processing, an output sequence including a term outside of the first vocabulary;
storing the output sequence in a non-transitory computer readable storage medium; and
providing the output sequence as a label recommendation for the unlabeled node.

11. A non-transitory computer readable storage medium as in claim 11 wherein the graph and the another graph comprise directed attributed graphs.

12. A non-transitory computer readable storage medium as in claim 11 wherein the processing comprises beam search.

13. A non-transitory computer readable storage medium as in claim 12 wherein the processing further comprises calculating an n-gram penalty.

14. A non-transitory computer readable storage medium as in claim 11 wherein the method further comprises:
also receiving from the processing, another output sequence;
ranking the output sequence and the other output sequence; and
providing the another output sequence as another label recommendation.

15. A computer system comprising:
one or more processors;
a software program, executable on said computer system, the software program configured to:
train a fine-tuned language model by,
extracting a training sequence from a process model comprising a graph in a process model repository stored in a database, the process model repository having a first vocabulary,
verbalizing the training sequence, and
providing the verbalized training sequence to a pre-trained language model;
receive an incomplete process model comprising another graph having an unlabeled node;
extract a sequence from the incomplete process model;
verbalize the sequence to create an input sequence;
process the input sequence as an activity-recommendation to the fine-tuned language model;
receive from the processing, an output sequence including a term outside of the first vocabulary;
store the output sequence in the database; and
provide the output sequence as a label recommendation for the unlabeled node.

16. A computer system as in claim 15 wherein the graph and the another graph comprise directed attributed graphs.

17. A computer system as in claim 15 wherein the processing comprises beam search.

18. A computer system as in claim 17 wherein the processing further comprises calculating an n-gram penalty.

19. A computer system as in claim 15 wherein the computer program is further configured to:
also receive from the processing, another output sequence;
rank the output sequence and the another output sequence; and
provide the another output sequence as another label recommendation

20. A computer system as in claim 19 wherein ranking applies a maximum strategy.
